(19) United States
(12) Patent Application Publication
(10) Pub. No.: US 2024/0040718 A1
(43) Pub. Date: Feb. 1, 2024

(54) DISPLAY PANEL

(71) Applicant: WUHAN CHINA STAR OPTOELECTRONICS SEMICONDUCTOR DISPLAY TECHNOLOGY CO., LTD., Hubei (CN)

(72) Inventor: Huan CAO, Wuhan, Hubei (CN)

(73) Assignee: Wuhan China Star Optoelectronics Semiconductor Display Technology Co., Ltd., Wuhan, Hubei (CN)

(21) Appl. No.: 17/623,623

(22) PCT Filed: Dec. 22, 2021
(86) PCT No.: PCT/CN2021/140457

§ 371 Date: Dec. 29, 2021

(30) Foreign Application Priority Data
Dec. 16, 2021 (CN) 202111546750.5

(51) Int. Cl. H05K 5/02

(52) U.S. Cl. CPC H05K 5/0217

(57) ABSTRACT

The embodiment of the present application provides a display panel. The display panel comprises a housing and a bending mechanism, and the bending mechanism further comprises a supporting plate, a folding plate and a lifting mechanism. The lifting mechanism comprises a lifting plate, a lifting paddle, a spring and a connecting spindle inside. When the connecting spindle rotates, it drives the lifting paddle to rotate. The lifting paddle moves the lifting plate to move the supporting plate therewith, thus to realize the unfolding and folding effect of the flexible screen.

### FIELD OF THE INVENTION

The present application relates to a manufacturing technical field of a display panel, and more particularly to a display panel.

### BACKGROUND OF THE INVENTION

With the development of display technology, foldable display panels or rollable display panels and the display devices have become an extremely important development direction of the display technology in the future.

A flexible display panel is a display panel that can be bent with a prescribed bending curvature. Compared with conventional display panels, flexible display panels have the advantages of being light and thin, not fragile, bendable, foldable and wearable. Therefore, flexible display panels are widely used in bendable and deformable electronic products, such as smart display terminals such as smart watches, smart phones and car monitors. However, in the foldable display device prepared in the prior art, when the flexible display panel is bent, the flexible screen is likely to interfere with other devices. Finally, after the flexible screen is bent, the flexible screen cannot be completely closed at the folding area, and there is no receding space in the foldable device at the folding area, which causes certain wrinkles in the flexible display screen and unsatisfactory folding effect.

Therefore, it is necessary to propose solutions to the issues in the prior art.

In summary, in the foldable display panel prepared in the prior art, when the display panel is folded, the flexible screen in the folding area cannot be completely closed, and in the folding area, the flexible screen is prone to wrinkles, and the folding effect is not ideal.

### SUMMARY OF THE INVENTION

In order to solve the aforesaid issues, the embodiment of the present application provides a display panel to effectively improve issues that in the existing foldable flexible display panel, as being folded, the flexible screen in the folding area cannot be completely closed, and in the folding area, the flexible screen is prone to wrinkles, and the folding effect is not ideal.

In order to solve the above technical problems, the technical methods provided by the embodiments of the present application are as follows:
first, the embodiment of the present application provides a display panel, comprising:
a housing, wherein the housing comprises a first housing and a second housing provided on a side of the first housing;
a bending mechanism, wherein the bending mechanism is arranged between the first housing and the second housing, and a bendable flexible screen is arranged on the bending mechanism;
wherein the bending mechanism comprises:
a supporting plate, wherein a torsion arm is provided on the supporting plate;
a folding plate, wherein the folding plate is connected to a side of the first housing and a side of the second housing correspondingly, and the folding plate is rotatably connected with the supporting plate through the torsion arm; and
a lifting mechanism, wherein the lifting mechanism is arranged on a side of the supporting plate, and the lifting mechanism comprises a lifting plate, and a connecting spindle connected to the lifting plate, and a lifting paddle fixed on the connecting spindle, and the folding plate rotates the connecting spindle and the lifting paddle, and an elastic device is further arranged between the lifting plate and the supporting plate, and the elastic device drives the lifting plate and the supporting plate to move synchronously to form a receding space.

According to one embodiment of the present application, an end of the lifting plate is provided with a spring hole, and a side of the supporting plate opposite to the spring hole is provided with a lifting plate screw, and the elastic device is sleeved on the lifting plate screw and connected with the spring hole.

According to one embodiment of the present application, receding slots are provided on both sides of the lifting plate close to the lifting plate screw, and the torsion arm passes through the receding slot and is connected with the folding plate.

According to one embodiment of the present application, the lifting mechanism further comprises a connecting spindle spring and a cam, and the connecting spindle spring is sleeved on the connecting spindle, and one end of the cam is in contact with the connecting spindle spring, and the other end of the cam is in contact with the torsion arm.

According to one embodiment of the present application, a plurality of sliding slots are provided at an end of the torsion arm connected with the connecting spindle, and the sliding slots are matched with the cam, and when the torsion arm rotates, the torsion arm drives the cam to rotate, and compresses or stretches the connecting spindle spring.

According to one embodiment of the present application, the cam comprises a protruding end and a flat end, and the protruding end faces a side of the torsion arm, and the flat end faces a side of connecting spindle spring.

According to one embodiment of the present application, the folding plate comprises a left folding plate and a right folding plate, and the left folding plate and the right folding plate are correspondingly arranged on both sides of the supporting plate, and the left folding plate and the right folding plate are symmetrically arranged with respect to a central axis of the bending mechanism.

Second, the embodiment of the present application further provides a display panel, comprising:
a housing, wherein the housing comprises a first housing and a second housing provided on a side of the first housing;
a bending mechanism, wherein the bending mechanism is arranged between the first housing and the second housing, and a bendable flexible screen is arranged on the bending mechanism;
wherein the bending mechanism comprises:
a supporting plate, wherein a torsion arm is provided on the supporting plate;
a folding plate, wherein the folding plate is connected to a side of the first housing and a side of the second housing correspondingly, and the folding plate is rotatably connected with the supporting plate through the torsion arm; and
a lifting mechanism, wherein the lifting mechanism is arranged on a side of the supporting plate, and the lifting mechanism comprises a lifting plate, and a connecting spindle connected to the lifting plate, and a lifting paddle fixed on the connecting spindle, and the folding plate rotates the connecting spindle and the lifting paddle, and an elastic device is further arranged between the lifting plate and the supporting plate, and the elastic device drives the lifting plate and the supporting plate to move synchronously to form a receding space.

According to one embodiment of the present application, an end of the lifting plate is provided with a spring hole, and a side of the supporting plate opposite to the spring hole is provided with a lifting plate screw, and the elastic device is sleeved on the lifting plate screw and connected with the spring hole.

According to one embodiment of the present application, receding slots are provided on both sides of the lifting plate close to the lifting plate screw, and the torsion arm passes through the receding slot and is connected with the folding plate.

According to one embodiment of the present application, the lifting mechanism further comprises a connecting spindle spring and a cam, and the connecting spindle spring is sleeved on the connecting spindle, and one end of the cam is in contact with the connecting spindle spring, and the other end of the cam is in contact with the torsion arm.

According to one embodiment of the present application, a plurality of sliding slots are provided at an end of the torsion arm connected with the connecting spindle, and the sliding slots are matched with the cam, and when the torsion arm rotates, the torsion arm drives the cam to rotate, and compresses or stretches the connecting spindle spring.

According to one embodiment of the present application, the cam comprises a protruding end and a flat end, and the protruding end faces a side of the torsion arm, and the flat end faces a side of connecting spindle spring.

According to one embodiment of the present application, two ends of the connecting spindle are connected with the lifting plate, and the lifting paddle, the connecting spindle spring, the cam and the torsion arm are sleeved on the connecting spindle in sequence, and the lifting paddle is arranged at an end close to the lifting plate.

According to one embodiment of the present application, the lifting paddles, the connecting spindle springs and the cams are symmetrically arranged with respect to the torsion arm.

According to one embodiment of the present application, the folding plate comprises a left folding plate and a right folding plate, and the left folding plate and the right folding plate are correspondingly arranged on both sides of the supporting plate, and the left folding plate and the right folding plate are symmetrically arranged with respect to a central axis of the bending mechanism.

According to one embodiment of the present application, the display panel further comprises a fixing bracket, and the fixing bracket is arranged at both ends of the bending mechanism, and the bending mechanism is connected to the housing through the fixing bracket.

According to one embodiment of the present application, the fixing bracket comprises a plurality of gears, gear through holes and spring holes, and the gear is arranged in the gear through hole, and an axis of the gear through hole is parallel to a surface of the supporting plate, and an axis of the spring hole is perpendicular to the surface of the supporting plate.

According to one embodiment of the present application, the gears comprises a first gear, a second gear, a third gear and a fourth gear that are sequentially engaged, and the first gear and the fourth gear are correspondingly connected with the connecting spindle, and the first gear and the fourth gear drive the second gear and the third gear to rotate synchronously.

According to one embodiment of the present application, the display panel further comprises a connecting plate, and two ends of the connecting plate are correspondingly connected with the torsion arm and the fixing bracket.

In conclusion, the benefits of the embodiments of the present application are:
the embodiment of the present application provides a display panel. The display panel comprises a housing and a bending mechanism, wherein the bending mechanism is arranged in a bending part of the housing, and the bending mechanism further comprises a supporting plate, a folding plate and a lifting mechanism. The lifting mechanism comprises a lifting plate, a lifting paddle, a spring and a connecting spindle inside. The spring is arranged between the lifting plate and the supporting plate, and the spring and the lifting paddle are both arranged on the connecting spindle. When the connecting spindle rotates, it drives the lifting paddle to rotate. The lifting paddle moves the lifting plate to move. When the lifting plate moves, under the linkage of the spring, the supporting plate moves accordingly, thus to realize the unfolding and folding effect of the flexible screen. The bending structure in the embodiment of the present application is simpler. When the flexible screen is unfolded and folded, there will be no wrinkles and other problems, and the display panel possesses a better folding and unfolding effect.

### BRIEF DESCRIPTION OF THE DRAWINGS

FIG. 1 is a structural diagram of a display panel provided by the embodiment of the present application;

FIG. 2 is a front view diagram of the bending mechanism;

FIG. 3 is a diagram of the back structure of the bending mechanism provided by the embodiment of the present application;

FIG. 4 is a diagram of the front state of the bending mechanism provided in the embodiment of the present application during the bending process;

FIG. 5 is a diagram of the back state of the bending mechanism provided in the embodiment of the present application during the bending process;

FIG. 6 is a structural diagram of a lifting mechanism provided in the embodiment of the present application;

FIG. 7 is a structural diagram of a lifting plate provided in the embodiment of the present application;

FIG. 8 is a top view diagram of the back of the lifting mechanism provided in the embodiment of the present application;

FIG. 9 is a structural diagram of the bending mechanism provided by the embodiment of the present application as bending;

FIG. 10 is another structural diagram of the bending mechanism provided by the embodiment of the present application as bending;

FIG. 11 is a side view diagram of the display panel provided in the embodiment of the present application after being completely folded;

FIG. 12 is a structural diagram of the supporting plate and the folding plate provided by the embodiment of the present application;

FIG. 13 is a diagram of a display panel provided by the embodiment of the present application as being folded;

FIG. 14 is a diagram of the disassembly of various components of the display panel provided in the embodiment of the present application.

### DETAILED DESCRIPTION OF PREFERRED EMBODIMENTS

The description of the following embodiments refers to the attached drawings to illustrate specific embodiments that the present disclosure can be implemented.

With the continuous development of display panel manufacturing technology, people have put forward higher requirements on the performance and quality of the display panel. It is hoped that the prepared display panel does not only possess better quality, but also possesses better overall performance.

For a flexible display panel, the folding performance of the display panel possesses an important influence on the display effect and display quality of the flexible screen. In the flexible folding panel prepared in the prior art, when the flexible screen is folded, the two opposite screens are often not well closed. For instance, there will be a certain bulge in the bending area of the screen, or squeezing will be formed between the film layers in the bending area and the film layers in the flat area, which will eventually cause folding problems such as wrinkles on the flexible screen in the display area. It will affect the further improvement for the comprehensive performance of the folding display panel.

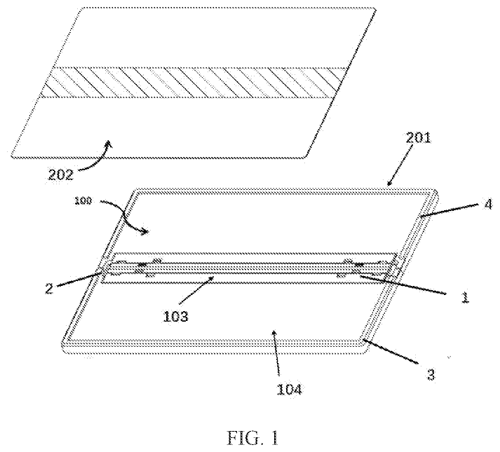

As shown in FIG. 1, FIG. 1 is a structural diagram of a display panel provided by the embodiment of the present application. Specifically, the display panel 100 comprises a flexible screen 202, a housing 201 and a bending mechanism 1. The flexible screen 202 can be laid on the housing 201 and deformed as the housing 201 is folded. For instance, the flexible screen 202 is bent in a corresponding area as the housing 201 is folded.

Specifically, the display panel 100 provided in the embodiment of the present application comprises a flattening area 104 and a bending area 103. The flattening area 104 is arranged on a side of the bending area 103. In the embodiment of the present application, the flattening area 104 is arranged on both sides of the bending area 103. When bending is performed, the bending area 103 in the middle is bent and deformed to the corresponding flexible screen, and the flattening areas 104 on both sides are overlapped, and ultimately the inward folding and closing effect of the display panel is realized. In the embodiment of the present application, after the display panel is completely folded, the flexible screen 202 forms a water drop-like bending shape in the bending area 103.

The housing 201 comprises a first housing 3 and a second housing 4. The supporting and fixing to the flexible screen 202 are realized by the first housing 3 and the second housing 4. In the embodiment of the present application, the first housing 3 and the second housing 4 are respectively arranged on both sides of the bending area 103 and are arranged symmetrically with respect to the central axis of the bending area 103. In order for the further description of the display panel, the first housing 3 uses the left middle frame, and the second housing 4 uses the right middle frame for description. When the display panel 100 is folded inward, the left middle frame and the right middle frame are respectively folded along the axis of the bending area 103 until the two middle frames are closed with each other.

In the embodiment of the present application, the bending mechanism 1 is arranged in the bending area 103, and the bending mechanism 1 is connected to the housing 201 through the connecting cover 2 so as to realize the fixing of the bending mechanism 1. When the display panel is folded inward, through the movement of the bending mechanism 1, the flexible screen 202 in the area is constrained, and the flexible screen in this area is deformed in a specific shape, and finally the bending effect of the flexible screen inside the foldable display panel is ensured.

Specifically, the bending mechanism 1 in the embodiment of the present application further comprises a supporting plate 160, a folding plate and a rotating slot 190. Specifically, the folding plate comprises a left folding plate 170 and a right folding plate 200. The left folding plate 170 and the right folding plate 200 are oppositely arranged according to the supporting plate 160. The left folding plate 170 and the right folding plate 200 are correspondingly arranged on both sides of the supporting plate 160. When the display panel is folded inward, the housing rotatably connected with the bending mechanism drives the folding plate on the same side to move. During the movement of the folding plate, it will drive the flexible screen to be bent and folded together. During the movement of the folding plate, the left folding plate 170 and the right folding plate 200 keep the synchronized movement, and are both rotated toward the center of the bending area.

Specifically, the bending mechanism 1 further comprises a lifting mechanism 208, and the lifting mechanism 208 is arranged on a side of the supporting plate 160. When the lifting mechanism 208 is provided, the lifting mechanism 208 is arranged on the side of the supporting plate 160 away from the flexible screen 200 to reduce the influence of the lifting mechanism 208 on the flexible screen 202.

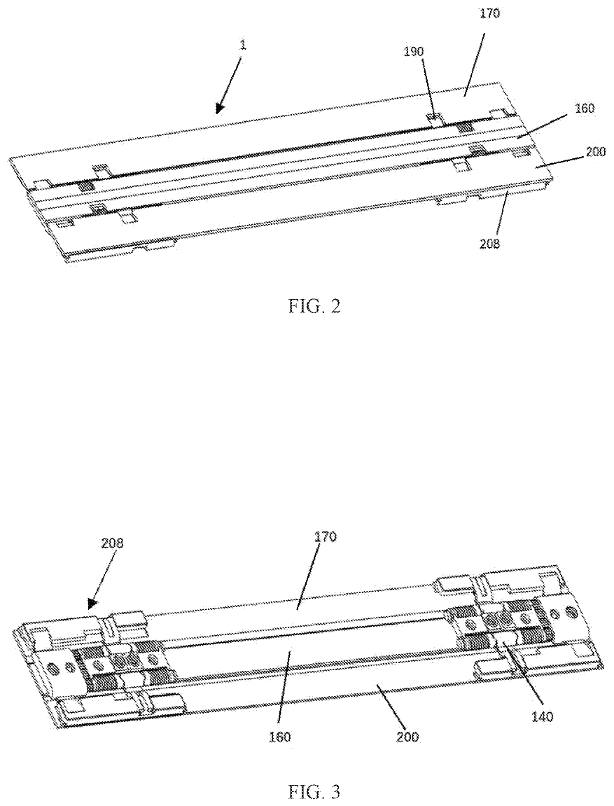

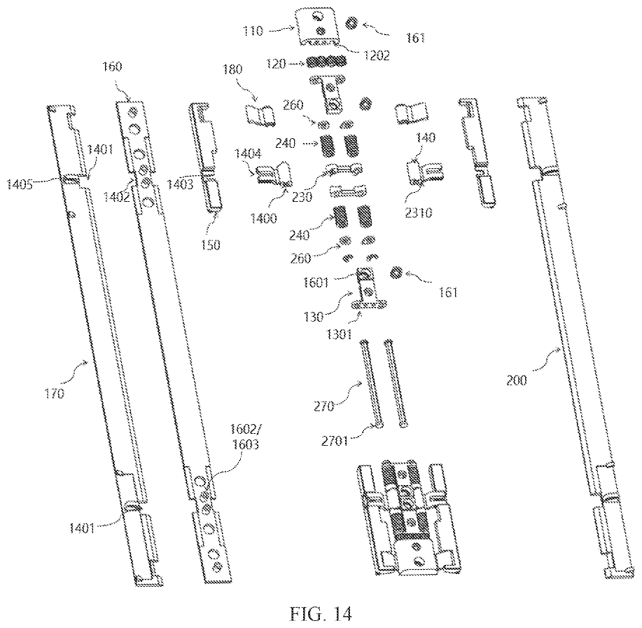

As shown in FIG. 3, FIG. 3 is a diagram of the back structure of the bending mechanism provided by the embodiment of the present application. As shown in FIG. 2 and FIG. 14, FIG. 2 is a front view diagram of the bending mechanism. In the embodiment of the present application, the lifting mechanisms 208 are arranged at both ends of the supporting plate 160. A torsion arm 140 is further provided on the supporting plate 160. The torsion arm 140 is connected to the edge of the supporting plate 160. In addition, at positions corresponding to the torsion arms 140, the left folding plate 170 and the right folding plate 200 are further provided with rotating slots 190.

Specifically, one end of the torsion arm 140 is connected to the edge of the supporting plate 160, and the other end of the torsion arm 140 is connected to the left folding plate 170 and the right folding plate 200 through a corresponding rotating slot 190. When the left folding plate 170 and the right folding plate 200 is folded inward, the torsion arm 140 connected thereto will be rotated accordingly. The torsion arm 140 will drive the supporting plate 160 to move during the rotation. In the embodiment of the present application, the torsion arm 140 is configured as an arc-shaped torsion arm to increase the range of force.

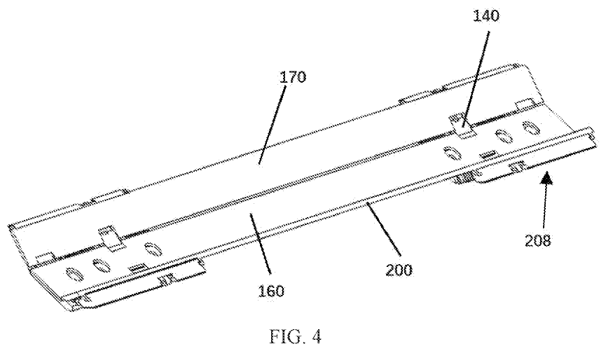

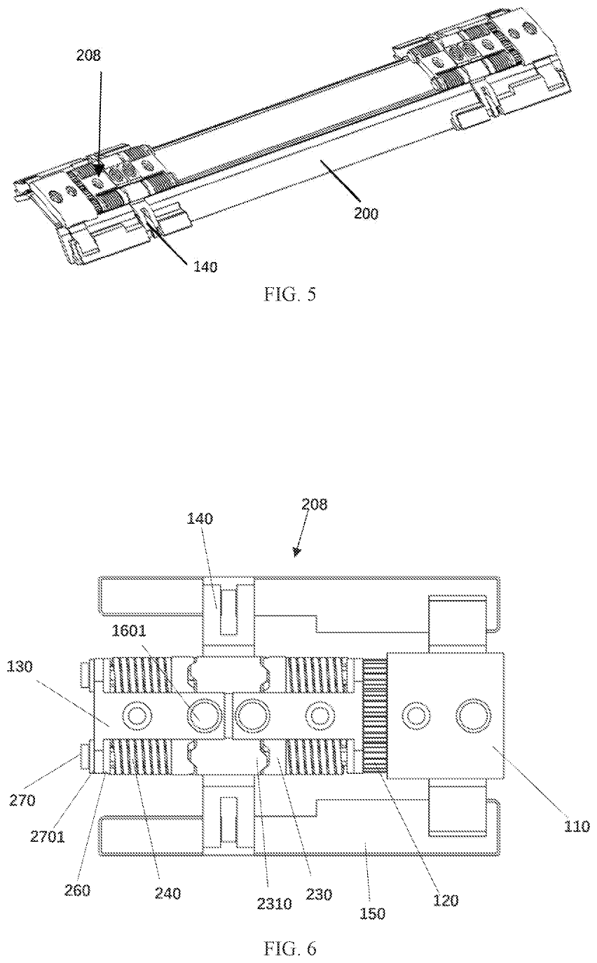

As shown in FIG. 4 and FIG. 5, FIG. 4 is a diagram of the front state of the bending mechanism provided in the embodiment of the present application during the bending process. FIG. 5 is a diagram of the back state of the bending mechanism provided in the embodiment of the present application during the bending process. FIG. 4 and FIG. 5 are corresponding diagrams of the left folding plate 170 and the right folding plate 200 after being bent at a certain angle. The folding plate will cause the flexible screen to bend. In the embodiment of the present application, as bending, when the left folding plate 170 gradually approaches the right folding plate 200, the corresponding flexible screen 202 at the bending area is deformed. When the corresponding flexible screens on the left folding plate 170 and the right folding plate 200 are in contact with each other, the display panel is completely folded.

Specifically, as shown in FIG. 6, FIG. 6 is a structural diagram of a lifting mechanism provided in the embodiment of the present application. In the embodiment of the present application, the lifting mechanism 208 further comprises a connecting spindle 270, a lifting paddle 260, a connecting spindle spring 240, a cam 230, a lifting plate 130 and a connecting plate 150. Specifically, the lifting plate 130 is configured as a T-shaped structure, with extending parts on both sides of one end. The positioning hole 1301 is provided in the extending part, and the connecting spindle 270 is inserted into the positioning hole 1301 to connect the lifting plate 130 on the other side of the connecting spindle 270. In the embodiment of the present application, the connecting spindle spring 240 may be an elastic member. Preferably, the connecting spindle spring 240 is illustrated for description.

One end of the torsion arm 140 is fixed on the connecting spindle 270, and the other end of the torsion arm 140 is fixedly connected with the corresponding folding plate and the connecting plate 150, to realize the fixing of the lifting mechanism through the connecting plate 150. In the embodiment of the present application, one end of the torsion arm 140 can be configured as a connecting through hole 1400, and the connecting spindle 270 is directly inserted into the connecting through hole 1400 to achieve the fixing. When the connecting through hole 1400 and the connecting spindle 270 are provided, they are designed as an interference fit, so as to ensure that the torsion arm 140 can drive the connecting spindle 270 to rotate. Furthermore, a sliding slot structure 2310 is provided on both sides of the connecting through hole 1400 of the torsion arm 140, and the sliding slot structure 2310 may be a plurality of sliding slots spaced apart.

In the embodiment of the present application, the lifting paddle 260 is fixedly arranged on the side of the connecting spindle 270 close to the extending part of the lifting plate 130. The lifting paddle 260 is configured as a special-shaped paddle, and the special-shaped part is arranged in the area where the lifting plate 130 is located. When the lifting paddle 260 is rotated with the connecting spindle 270, the special-shaped part will be rotated to the edge of the lifting plate 130 and apply pressure or pulling force to the lifting plate 130. In the embodiment of the present application, a snap ring is further provided on the connecting spindle, and the lifting paddle 260 is restricted by the snap ring to prevent the lifting paddle from sliding. The structure of the snap ring is not specified, as long as it can be installed on the connecting spindle and prevent the lifting paddle 260 from sliding.

Meanwhile, the connecting spindle spring 240 and the cam 230 are sequentially arranged on the connecting spindle 270. One end of the cam 230 is configured as a flat end surface, and the flat end surface is opposite to the connecting spindle spring 240. The other end of the cam 230 is configured as a convex-concave structure, and the convex-concave structure end is opposite to one end of the torsion arm 140.

In the embodiment of the present application, the cam 230 is sleeved on the connecting spindle, and the cam 230 comprises a protruding end 2301 and a flat end 2302. The protruding end 2301 is configured toward one end of the torsion arm 140, and the flat end 2302 is configured toward the connecting spindle spring 240. The protruding end 2301 can be provided with the convex-concave structure to cooperate with the torsion arm.

When the torsion arm drives the connecting spindle 270 to rotate, the sliding slot structure 2310 corresponding to the concave structure on the torsion arm 140 will be correspondingly rotated into the convex-concave structure of the cam 230. During the rotation, the torsion arm exerts a thrust on the cam, and the thrust is further transferred to the connecting spindle spring 240, so that the connecting spindle spring 240 generates elastic force to stretch or compress. Under the action of the elastic force of the connecting spindle spring 240, each component is maintained at a predetermined position.

In the embodiment of the present application, on the same connecting spindle 270 and at both sides of the torsion arm 140, the connecting spindle springs 240, the cams 230, the lifting paddles 260 and the lifting plates 130 can be arranged symmetrically with respect to the torsion arm. The lifting paddle 260 is arranged close to one end of the lifting plate 130, thereby reducing the size of the lifting mechanism and ensuring the movement effect of the lifting mechanism.

Furthermore, in order to fix the connecting spindle 270, a spindle cap 2701 is further provided at both ends of the connecting spindle 270. The shaft caps 2701 are employed to fix the connecting spindle 270 and the lifting plate 130 to effectively prevent the connecting spindle 270 from rotating out of the corresponding connecting through hole 1400 during the rotation.

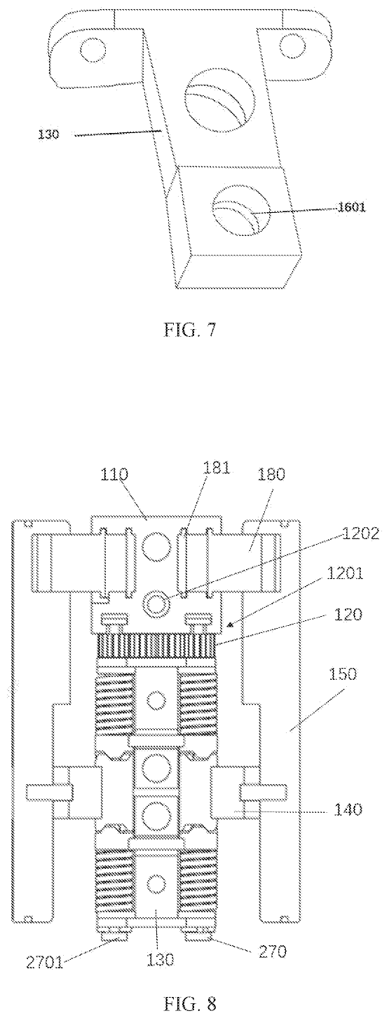

As shown in FIG. 7, FIG. 7 is a structural diagram of a lifting plate provided in the embodiment of the present application. Specifically, a screw hole 1601 is further provided on the lifting plate 130. The screw hole 1601 can be provided in multiple, and the screw hole 1601 is correspondingly provided with a thread, and the screw hole 1601 is configured as a blind hole. When the connection is implemented, the screw hole 1601 corresponds to the screw provided on the supporting plate 160, so as to realize the connection between the lifting plate 130 and the supporting plate 160, as shown in the structure in FIG. 6 and FIG. 7. In the embodiment of the present application, an elastic device, such as a spring 161, is arranged in the screw hole 1601. When the screw hole 1601 is installed and fixed with the screw 1602 and the screw 1603, the spring 161 is compressed in the screw hole 1601. Since the spring is compressed in the screw hole 1601, when the lifting paddle 260 exerts a force on the lifting plate 130, the lifting plate 130 will drive the supporting plate 160 to move under the action of the spring 161 and the screw 1602. Therefore, when the display panel is folded inward, a receding space is provided for the flexible screen, so as to effectively prevent problems such as wrinkles of the flexible screen in the folding area.

Furthermore, on both sides of the supporting plate 160 close to the screw 1602 of the lifting plate, the receding slots 1402 are further provided, and the receding slots 1402 are symmetrically arranged with respect to the center line of the lifting plate. In the embodiment of the present application, the torsion arm 140 is further provided with an aligning slot 1404. A fixing part 1405 is provided on the left folding plate 170 opposite to the aligning slot 1404. As installing the torsion arm 140, the torsion arm 140 sequentially passes through another receding slot 1403 on the connecting plate 150, the receding slot 1402 on the supporting plate 160 and the receding slot 1401 on the left folding plate 170. Then, the aligning slot 1404 on the torsion arm 140 is engaged with the fixing part 1405 of the left folding plate 170, so as to realize the installation and fixing of the aforesaid components.

In the embodiment of the present application, as shown in FIG. 8, FIG. 8 is a top view diagram of the back of the lifting mechanism provided in the embodiment of the present application. At the same time, combined with the structure in FIG. 6, the display panel further comprises a fixing bracket 110, the fixing bracket 110 is arranged at both ends of the bending mechanism, and the fixing bracket 110 is connected with the lifting mechanism. Specifically, the fixing bracket 110 comprises a plurality of gears 120, and also comprises gear through holes 1201 and spring holes 1202 corresponding to the plurality of gears 120 at the same time. In the embodiment of the present application, the first gear, the second gear, the third gear and the fourth gear are illustrated for the gears 120. The first gear, the second gear, the third gear and the fourth gear may be arranged side by side on one end of the fixing bracket 110, and correspondingly installed in the corresponding gear through holes 1201. The axis of the gear through hole 1201 is parallel to the surface of the supporting plate, and the axis of the spring hole 1202 is perpendicular to the surface of the supporting plate. Meanwhile, the fixing bracket 110 is further provided with a rotating slide 181 and a connecting arm 180. One end of the connecting arm 180 is arranged in the rotating slide 181. The connecting arm 180 is configured as an arc-shaped curved arm, and the other end of the connecting arm 180 is connected to the connecting plate 150. The connecting plate 150 relies on the connecting arm 180 to be rotated relative to the fixing bracket 110, and a spring is arranged in the spring hole 1202 to realize the housing fixing of the fixing bracket 110.

As shown in FIG. 8, the gear 120 comprises the first gear, his second gear, his third gear and his fourth gear in sequence from left to right. The first gear and the fourth gear are connected with the connecting spindles 270 on the corresponding side. When the connecting spindle 270 is rotated under the action of the connecting plate 150, the connecting spindle 270 will drive the first gear and the fourth gear to rotate. Since adjacent gears are engaged with each other, the first gear and the fourth gear drive the second gear and the third gear to rotate, respectively. Therefore, the first gear and the fourth gear are equivalent to the driving wheel, and the second gear and the third gear are the driven wheels. In the embodiment of the present application, the first gear and the fourth gear have the same modulus and the number of teeth, while the second gear and the third gear have the same modulus and the number of teeth. Preferably, it is also possible to arrange the respective various gears to have the same modulus and number of teeth. Thus, the folding plates on both sides can realize synchronous rotation, and the inward folding effect of the flexible screen is ensured.

Meanwhile, in the embodiment of the present application, as configuring the connecting spindle 270, the end of the connecting spindle 270 connected with the gear is in an interference fit with the gear. Thus, the connecting spindle 270 can be firmly sleeved with the gear to drive the gear to rotate, and a spindle cap 2701 is also provided at the other end of the connecting spindle 270. After the connecting spindle 270 is connected to the lifting plate 130, the spindle cap 2701 is clamped on the end of the connecting spindle 270. Accordingly, the fixation and installation of various components are accomplished.

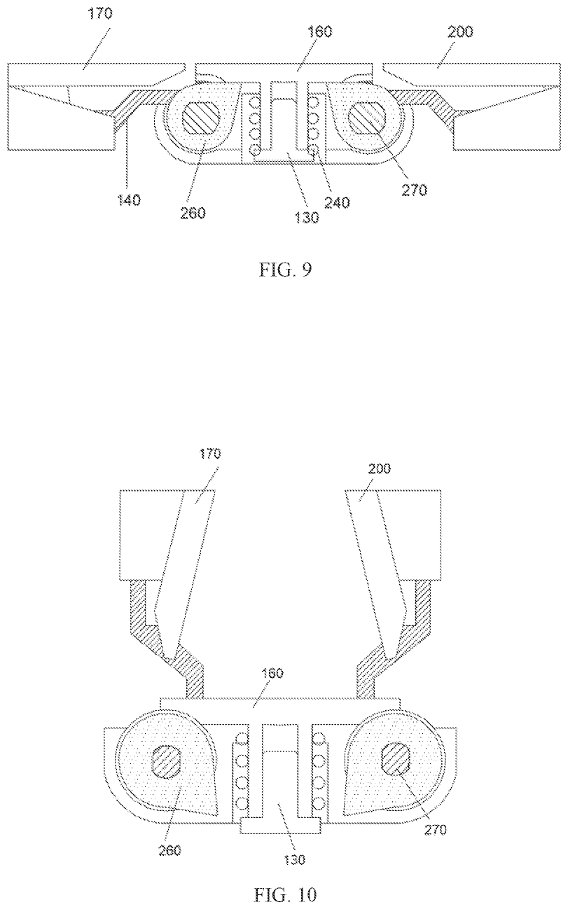

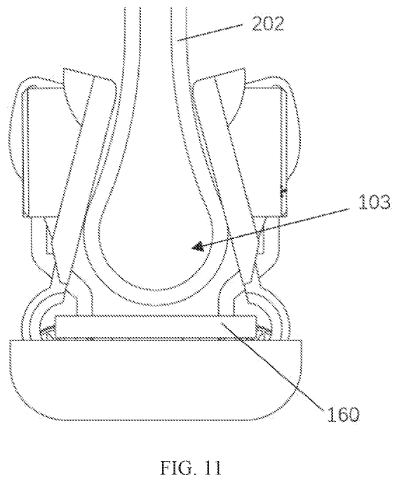

Furthermore, as shown in FIG. 9 to FIG. 10, FIG. 9 to FIG. 10 are structural diagrams of the bending mechanism provided by the embodiment of the present application as bending. When the display panel is in a flattening state, that is, when the first housing and the second housing are not relatively folded, the left folding plate 170, the right folding plate 200 and the supporting plate 160 may be located in the same plane. At this time, the lifting paddle 260 fixed on the connecting spindle 270 to push the supporting plate 160 to prevent the supporting plate 160 from declining. When the folding plate is rotated, the lifting paddle 260 sleeved on the connecting spindle 270 is rotated with the spindle, and recedes to enlarging the distance from the middle lifting plate 130. The lifting plate 130 is pulled down by driving of the spring, thereby generating a certain space for receding. That is, in the vertical direction, the height of the supporting plate 160 is reduced, so that a certain bending space is reserved for the flexible screen, and the inward folding effect of the display panel is improved.

Meanwhile, in conjunction with the component structures in FIG. 1 to FIG. 8, and FIG. 14, the torsion arm 140 in the embodiment of the present application is configured as an arc-shaped torsion arm. When the arc-shaped torsion arm is rotated, it can control the relative position of the left and right folding plates and the folding angle; In addition, when the structure such as sliding slot provided on the connecting spindle connected to the torsion arm 140 and at the corresponding position is rotated, the cooperated sliding slot and cam will expand and contract according to the folding and rotating dislocations to compensate for the displacement for each other.

Meanwhile, the cam further compresses the spring and generates thrust, and the torsion arm 140 drives the connecting spindle 270 to rotate through the flat position in the inner hole of the cam structure. Then, the connecting spindle 270 drives the gear 120 sleeved thereon to rotate. The gear is engaged with adjacent gear, which in turn drives the spindle on the other side to rotate, so that the other side can move synchronously. In the meantime, the supporting plate 160 opposite to the flexible screen 202 moves and sinks under the action of the connecting spindles, the lifting paddles, the springs and the lifting plates, thus reserving a certain receding distance for the flexible screen 202, so as to realize the folding process of the panel.

As shown in FIG. 11, FIG. 11 is a side view diagram of the display panel provided in the embodiment of the present application after being completely folded. When the left and right folding plates are folded to a predetermined position, the flexible screens 202 arranged on the left and right folding plates will approach or almost get in contact with each other, and the flexible screen 202 is bent into a water drop-like structure at the bending area 103 of the display panel. When the display panel is from the fully folding state to the flattening state, the movement process of the left and right folding plates is the same as the foregoing action. Only at this time, when the lifting paddle 260 arranged on the connecting spindle 270 is rotated with the spindle, to gradually approach the lifting plate 130, and lift the lifting plate 130 from both sides of the bottom of the lifting plate 130 until the lifting plate 130 is raised to a level state.

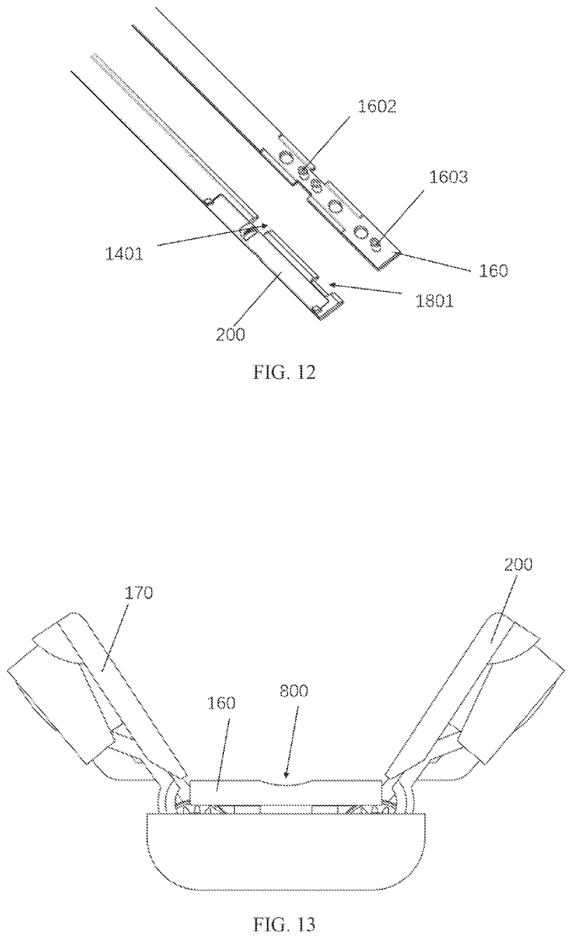

Specifically, as shown in FIG. 12, FIG. 12 is a structural diagram of the supporting plate and the folding plate provided by the embodiment of the present application. Specifically, the supporting plates 160 and the folding plates are both symmetrical structures. Therefore, parts of the supporting plate and the right folding plate 200 are illustrated for descriptions of the aforesaid supporting plate 160. The screw 1602 and the screw 1603 are provided on the supporting plates 160. Meanwhile, by cooperating with the structure of the lifting plate in FIG. 8, the screw hole 1601 provided on the lifting plate 130 will correspond to the screw 1602, and a spring is installed on the screw 1602. In the embodiment of the present application, two screws 1602 are provided on one side of the supporting plate 160, so that two lifting plates 130 are correspondingly provided in this area. When the lifting paddle acts on the lifting plate 130, the lifting plate 130 will move the supporting plate 160 along therewith under the action of the screws and springs, thereby providing a receding space for the flexible screen.

Furthermore, in the embodiment of the present application, the screw 1603 is further provided on the supporting plate 160, and the screw 1603 is connected with a corresponding screw hole on the fixing bracket, and a spring is also arranged on the screw 1603. In the meantime, a sliding slot 1401 and a sliding slot 1801 are provided on the right folding plate 200. The sliding slots are respectively connected with the torsion arm and the connecting arm. When the right folding plate 200 is moved, the connecting spindle is driven to move by the torsion arm and the connecting arm connected thereto. Meanwhile, in the embodiment of the present application, a slide is further provided in the sliding slot 1401, so as to ensure that the torsion arm does not displace during the rotation, and ultimately realize the folding of the display panel.

Furthermore, as shown in FIG. 13, FIG. 13 is a diagram of a display panel provided by the embodiment of the present application as being folded. In the embodiment of the present application, the supporting plate 160 is further provided with a receding groove 800. The receding groove 800 is arranged on the surface of the supporting plate 160, and is arranged in an arc shape on the surface. After the flexible screen is completely folded inward, the shape of the folded end is a water drop-like shape. Therefore, the receding groove can well support the water drop part of the flexible screen, thereby ensuring the folding effect of the flexible screen.

Furthermore, as shown in FIG. 14, FIG. 14 is a diagram of the disassembly of various components of the display panel provided in the embodiment of the present application. The components involved in FIG. 14 are the corresponding components introduced in FIG. 1 to FIG. 13. When the respective components are installed, they are assembled according to the corresponding cooperating structure and the realized functions, and ultimately form the display panel provided in the embodiment of the present application.

When the display panel provided in the embodiment of the present application is folded inward, the flexible screen is folded into a water drop-like structure in the bending area of the display panel. As observing from outside the display panel, the overall closed appearance of the device can be achieved. This effectively ensures that the flexible screen still possesses excellent performance after the display panel is folded, and there will be no quality problems such as wrinkles in the bending area.

The display panel provided by the embodiments of the present application is described in detail as aforementioned, and the principles and implementations of the present application have been described with reference to specific illustrations. The description of the foregoing embodiments is merely for helping to understand the technical solutions of the present application and the core ideas thereof; those skilled in the art should understand that the technical solutions described in the foregoing embodiments may be modified, or some of the technical features may be equivalently replaced; and the modifications or replacements do not deviate from the spirit and scope of the technical solutions of the embodiments of the present application.

What is claimed is:

1. A display panel, comprising:
a housing, wherein the housing comprises a first housing and a second housing provided on a side of the first housing;
a bending mechanism, wherein the bending mechanism is arranged between the first housing and the second housing, and a bendable flexible screen is arranged on the bending mechanism;
wherein the bending mechanism comprises:
a supporting plate, wherein a torsion arm is provided on the supporting plate;
a folding plate, wherein the folding plate is connected to a side of the first housing and a side of the second housing correspondingly, and the folding plate is rotatably connected with the supporting plate through the torsion arm; and
a lifting mechanism, wherein the lifting mechanism is arranged on a side of the supporting plate, and the lifting mechanism comprises a lifting plate, and a connecting spindle connected to the lifting plate, and a lifting paddle fixed on the connecting spindle, and the folding plate rotates the connecting spindle and the lifting paddle, and an elastic device is further arranged between the lifting plate and the supporting plate, and the elastic device drives the lifting plate and the supporting plate to move synchronously to form a receding space, wherein one end of the torsion arm connected with the connecting spindle is configured as a connecting through hole, and the connecting spindle is inserted into the connecting through hole and fixed.

2. The display panel according to claim 1, wherein an end of the lifting plate is provided with a spring hole, and a side of the supporting plate opposite to the spring hole is provided with a lifting plate screw, and the elastic device is sleeved on the lifting plate screw and connected with the spring hole.

3. The display panel according to claim 2, wherein receding slots are provided on both sides of the lifting plate close to the lifting plate screw, and the torsion arm passes through the receding slot and is connected with the folding plate.

4. The display panel according to claim 1, wherein the lifting mechanism further comprises a connecting spindle spring and a cam, and the connecting spindle spring is sleeved on the connecting spindle, and one end of the cam is in contact with the connecting spindle spring, and the other end of the cam is in contact with the torsion arm.

5. The display panel according to claim 4, wherein a plurality of sliding slots are provided at an end of the torsion arm connected with the connecting spindle, and the sliding slots are matched with the cam, and when the torsion arm rotates, the torsion arm drives the cam to rotate, and compresses or stretches the connecting spindle spring.

6. The display panel according to claim 5, wherein the cam comprises a protruding end and a flat end, and the protruding end faces a side of the torsion arm, and the flat end faces a side of connecting spindle spring.

7. The display panel according to claim 1, wherein the folding plate comprises a left folding plate and a right folding plate, and the left folding plate and the right folding plate are correspondingly arranged on both sides of the supporting plate, and the left folding plate and the right folding plate are symmetrically arranged with respect to a central axis of the bending mechanism.

8. A display panel, comprising:
a housing, wherein the housing comprises a first housing and a second housing provided on a side of the first housing;
a bending mechanism, wherein the bending mechanism is arranged between the first housing and the second housing, and a bendable flexible screen is arranged on the bending mechanism;
wherein the bending mechanism comprises:
a supporting plate, wherein a torsion arm is provided on the supporting plate;
a folding plate, wherein the folding plate is connected to a side of the first housing and a side of the second housing correspondingly, and the folding plate is rotatably connected with the supporting plate through the torsion arm; and
a lifting mechanism, wherein the lifting mechanism is arranged on a side of the supporting plate, and the lifting mechanism comprises a lifting plate, and a connecting spindle connected to the lifting plate, and a lifting paddle fixed on the connecting spindle, and the folding plate rotates the connecting spindle and the lifting paddle, and an elastic device is further arranged between the lifting plate and the supporting plate, and the elastic device drives the lifting plate and the supporting plate to move synchronously to form a receding space.

9. The display panel according to claim 8, wherein an end of the lifting plate is provided with a spring hole, and a side of the supporting plate opposite to the spring hole is provided with a lifting plate screw, and the elastic device is sleeved on the lifting plate screw and connected with the spring hole.

10. The display panel according to claim 9, wherein receding slots are provided on both sides of the lifting plate close to the lifting plate screw, and the torsion arm passes through the receding slot and is connected with the folding plate.

11. The display panel according to claim 8, wherein the lifting mechanism further comprises a connecting spindle spring and a cam, and the connecting spindle spring is sleeved on the connecting spindle, and one end of the cam is in contact with the connecting spindle spring, and the other end of the cam is in contact with the torsion arm.

12. The display panel according to claim 11, wherein a plurality of sliding slots are provided at an end of the torsion arm connected with the connecting spindle, and the sliding slots are matched with the cam, and when the torsion arm rotates, the torsion arm drives the cam to rotate, and compresses or stretches the connecting spindle spring.

13. The display panel according to claim 12, wherein the cam comprises a protruding end and a flat end, and the protruding end faces a side of the torsion arm, and the flat end faces a side of connecting spindle spring.

14. The display panel according to claim 8, wherein two ends of the connecting spindle are connected with the lifting plate, and the lifting paddle, the connecting spindle spring, the cam and the torsion arm are sleeved on the connecting spindle in sequence, and the lifting paddle is arranged at an end close to the lifting plate.

15. The display panel according to claim 14, wherein the lifting paddles, the connecting spindle springs and the cams are symmetrically arranged with respect to the torsion arm.

16. The display panel according to claim 8, wherein the folding plate comprises a left folding plate and a right folding plate, and the left folding plate and the right folding plate are correspondingly arranged on both sides of the supporting plate, and the left folding plate and the right folding plate are symmetrically arranged with respect to a central axis of the bending mechanism.

17. The display panel according to claim 8, wherein the display panel further comprises a fixing bracket, and the fixing bracket is arranged at both ends of the bending mechanism, and the bending mechanism is connected to the housing through the fixing bracket.

18. The display panel according to claim 17, wherein the fixing bracket comprises a plurality of gears, gear through holes and spring holes, and the gear is arranged in the gear through hole, and an axis of the gear through hole is parallel to a surface of the supporting plate, and an axis of the spring hole is perpendicular to the surface of the supporting plate.

19. The display panel according to claim 18, wherein the gears comprises a first gear, a second gear, a third gear and a fourth gear that are sequentially engaged, and the first gear and the fourth gear are correspondingly connected with the connecting spindle, and the first gear and the fourth gear drive the second gear and the third gear to rotate synchronously.

20. The display panel according to claim 1, wherein the display panel further comprises a connecting plate, and two ends of the connecting plate are correspondingly connected with the torsion arm and the fixing bracket.
